(19) United States
(12) Patent Application Publication
(10) Pub. No.: US 2011/0226519 A1
(43) Pub. Date: Sep. 22, 2011

(54) Electric Connection Structure And Method For Fabricating The Same

(76) Inventors: Wei-Chun Yang, Gueishan Township (TW); Pi Hsi Cheng, Gueishan Township (TW); Chun Yang Li, Gueishan Township (TW)

(21) Appl. No.: 12/726,345

(22) Filed: Mar. 18, 2010

(51) Int. Cl. H05K 1/11; H05K 3/00

(52) U.S. Cl. 174/263; 29/843

(57) ABSTRACT

An electric connection structure and a method for fabricating the same are provided. The present invention provides a fixing thread fixed to a substrate and disposed on an upper surface of the substrate. The fixing thread is fixed to the substrate by shuttling between, binding, or penetrating through the upper surface and the bottom surface of the substrate. And then, a bare end of a signal line is fixed to the upper surface of the substrate by welding a solder thereby. When the solder is cooled down to solidify, the fixing thread generates a pull force applied on the solder pulling the solder toward the upper surface of the substrate.

### BACKGROUND OF THE INVENTION

1. Field of the Invention

The present invention relates generally to an electric connection structure and a method for fabricating the same, and more particularly, to an electric connection structure and a method for fabricating the same, which are adapted for achieving an improved bondability between a solder and a substrate.

2. The Prior Arts

Generally, when a current is intended to be directed in or out a circuit configured on a metal thin film substrate, an external metal-made electric connection line is often welded with a solder onto the substrate for serving as an interconnection member. However, in a mass production, there are always a certain percentage of products having the problem of electric connection line breaking away from the substrate. This is most likely because of the unsatisfactory bondability between the solder and the substrate, and usually drastically increases the production cost.

Further, in accordance with a conventional technology, when a substrate module is desired to be fixed to a structure or a device, the substrate module is usually secured to a carrier, and is then fixed to the structure or the device by fixing the carrier to the structure or device. However, when the substrate module is desired to be fixed to a cloth or other flexible items, the conventional technology is not a good choice. Although the substrate module can also be fixed to the cloth or flexible item by securing the substrate module to a carrier first and then fixing the carrier to the cloth or flexible item, this process is relatively complicated and unavoidably increases the production cost.

### SUMMARY OF THE INVENTION

A primary objective of the present invention is to provide an electric connection structure and a method for fabricating the same, which are adapted for achieving an improved bondability between a solder and a substrate.

For achieving the foregoing objective and others, the present invention provides a fixing thread fixed to a substrate and disposed on an upper surface of the substrate. Such a fixing thread is adapted for improving the bondability between a solder provided on the upper surface of the substrate and the substrate.

Specifically, the present invention provides a method for fabricating an electric connection structure. The method includes the following steps. First, a fixing thread is fixed to a substrate and disposed on an upper surface of the substrate. Then, a solder is used for welding a signal line to the upper surface of the substrate where the fixing thread is disposed thereon. The present invention further provides an electric connection structure. The electric connection structure includes a substrate, at least a fixing thread, and a solder. The fixing thread is disposed on an upper surface of the substrate fixed to the substrate by sewing the fixing thread through the substrate. The solder is welded on the upper surface of the substrate where the fixing thread is disposed thereon. When the solder is cooled down and solidified, the fixing thread presents a pulling force relative to the solder, and the pulling force facilitates to improve the bondability of the solder to the substrate.

### BRIEF DESCRIPTION OF THE DRAWINGS

The present invention will be apparent to those skilled in the art by reading the following detailed description of preferred embodiments thereof, with reference to the attached drawings, in which:

FIG. 1 is a flow chart illustrating the procedure of the method for fabricating an electric connection structure according to an embodiment of the present invention;

FIG. 2 is a schematic diagram illustrating the components of the present invention;

FIG. 3 is a first cross-sectional view of an electric connection structure according to a first embodiment of the present invention;

FIG. 4 is a second cross-sectional view of an electric connection structure according to a first embodiment of the present invention;

FIG. 5 is a cross-sectional view of an electric connection structure according to a second embodiment of the present invention; and

FIG. 6 is a cross-sectional view of an electric connection structure according to a third embodiment of the present invention.

### DETAILED DESCRIPTION OF THE PREFERRED EMBODIMENT

The accompanying drawings are included to provide a further understanding of the invention, and are incorporated in and constitute a part of this specification. The drawing illustrates embodiments of the invention and, together with the description, serves to explain the principles of the invention.

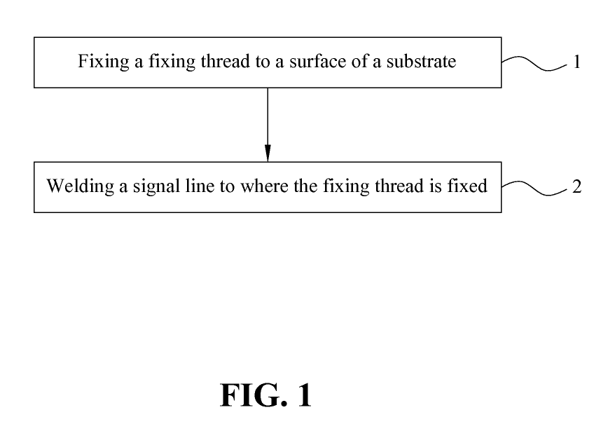

FIG. 1 is a flow chart illustrating the procedure of the method for fabricating an electric connection structure according to an embodiment of the present invention. Referring to FIG. 1, at step 1, a fixing thread is fixed to a substrate so as to be disposed on an upper surface of the substrate. The fixing thread for example can be fixed to the substrate in a manner of sewing the fixing thread onto the substrate or binding the fixing thread to the substrate. Then, at step 2, a solder is used to weld a signal line onto the upper surface of the substrate at where the fixing thread is fixed. In accordance with the step 2, an end of the signal line is positioned on the upper surface of the substrate at where the fixing thread is fixed, and the solder is heated to melt on the end of the signal line. The molten solder slowly cools down to solidify so as to fix the end of the signal line to the substrate. Meanwhile, the fixing thread generates a pulling force applied on the solder for pulling the solder toward the substrate. In such a way, the bondability between the solder and the upper surface of the substrate is correspondingly improved.

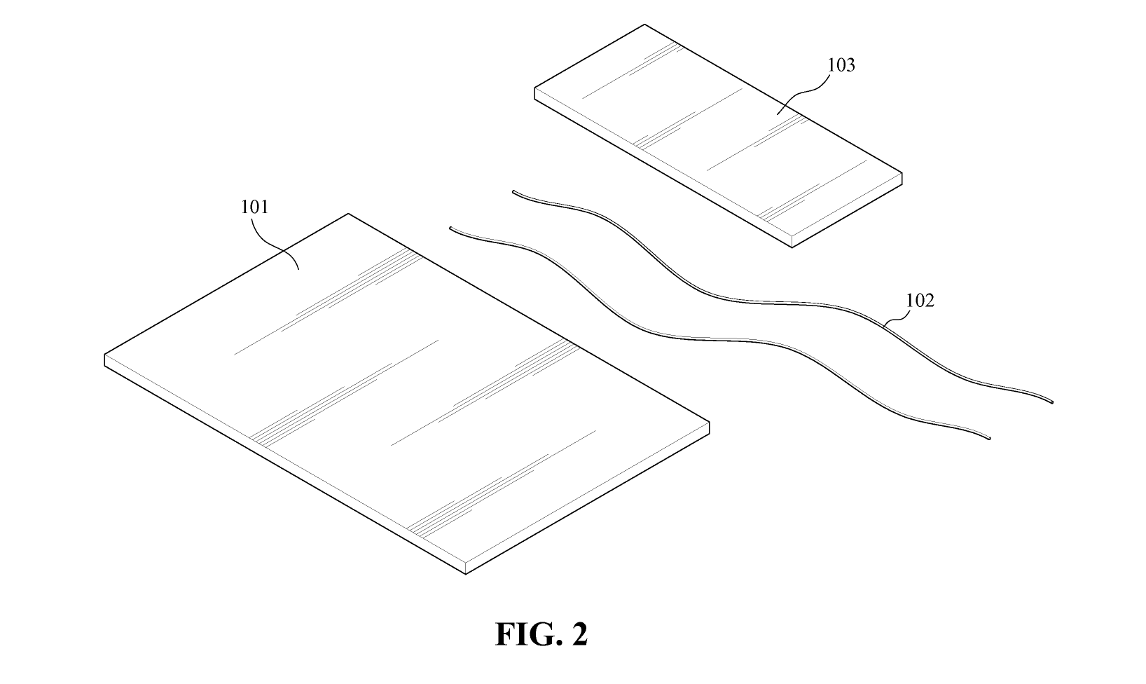

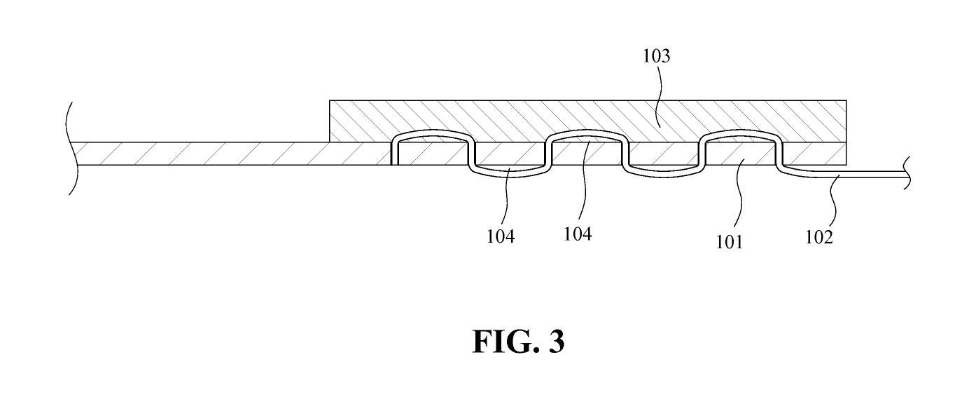

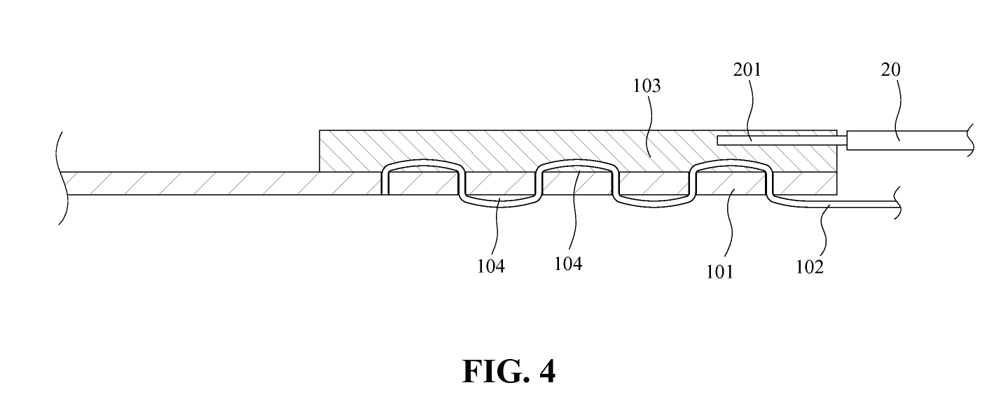

FIG. 2 is a schematic diagram illustrating the components of the present invention. FIG. 3 is a first cross-sectional view of an electric connection structure according to a first embodiment of the present invention. FIG. 4 is a second cross-sectional view of an electric connection structure according to a first embodiment of the present invention. Referring to FIGS. 2, 3, and 4 together, there is shown an electric connection structure. The electric connection structure includes a substrate 101, at least one fixing thread 102, and a solder 103. The fixing thread 102 is fixed to the substrate 101 by repetitively and alternatively sewing the fixing thread 102 over an upper surface and a bottom surface of the substrate 101, so that the fixing thread 102 includes a plurality of sections alternatively shuttling between the upper surface and the bottom surface of the substrate 101. Further, there is a free space 104 defined between each section of the fixing thread 102 and the upper surface or bottom surface of the substrate 101. The solder 103 is then provided on the upper surface of the substrate at where the fixing thread 102 is fixed thereto. The solder 103 is then heated to melt, so that the molten solder 103 covers the fixing thread 102, and fills in the free space 104 on the upper surface of the substrate 101. In such a way, when the solder 103 cools down to solidify, the fixing thread 102 extends through the solder 103 and generates a pulling force applied on the solidified solder 103, thus improving the bondability between the solder 103 and the substrate 101. Further, it should be noted that during the process of welding the solder 103 onto the upper surface of the substrate 101, a bare end 201 of a signal line 20 is put on the upper surface of the substrate 101, so that the bare end 201 is welded together with the solder 103 onto the upper surface of the substrate 101. Further, according to a further embodiment of the present invention, the fixing thread 102 is used to sew one surface of the substrate 101 onto an external object, and the other surface of the substrate 101 is provided for welding with the solder 103.

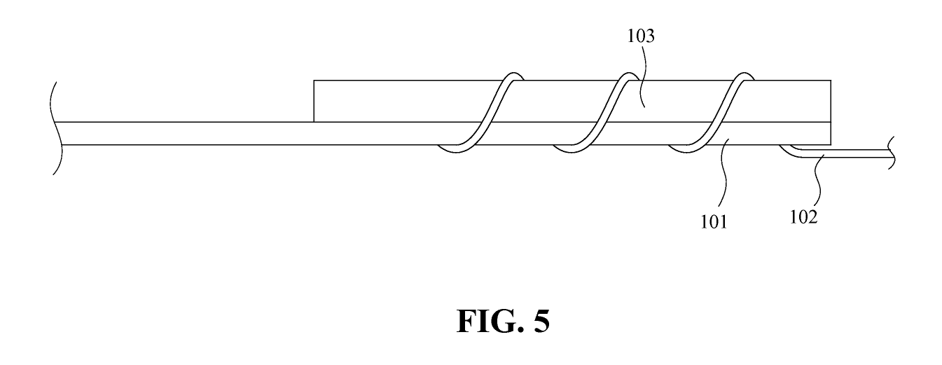

FIG. 5 is a cross-sectional view of an electric connection structure according to a second embodiment of the present invention. Referring to FIG. 5, in accordance with the second embodiment of the present invention, a solder 103 is welded and solidified on an upper surface of a substrate 101. Then, a fixing thread 102 is used to wind up the substrate 101 with the solder 103, so as to bind the solder 103 onto the upper surface of the substrate 101. Further, according to an aspect of the second embodiment, the substrate 101 is configured with several through holes (not shown in the drawings) positioned nearby the position where solder 103 is welded for allowing the fixing thread 102 extending therethrough for binding the upper surface and a bottom surface of the substrate 101 together with the solder 103, thus securing the solder 103 onto the upper surface of the substrate 101.

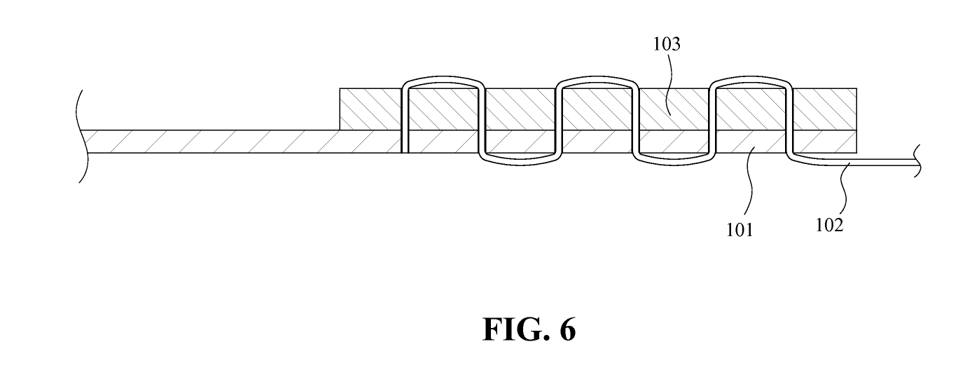

FIG. 6 is a cross-sectional view of an electric connection structure according to a third embodiment of the present invention. Referring to FIG. 6, in accordance with the third embodiment of the present invention, a solder 103 is welded and solidified on an upper surface of a substrate 101. A computer sewing machine or the like is used to sew the substrate 101 together with the solder 103 with a fixing thread 102. In such a way, an improved bondability between the solder 103 and the substrate 101 is achieved.

In accordance with foregoing embodiments, the fixing thread 102 for example can be made of a conductive material, e.g., copper, or iron. The substrate 101 for example is prepared with a metal thin film processing. Specifically, a metal thin film is coated on the upper surface of the substrate 101, and then an etching process is executed to form a circuit layout. Or alternatively, a pre-configured metal thin film is attached to the upper surface of the substrate 101.

In accordance with a further embodiment of the present invention, the electric connection structure further includes a conductive thin film. The conductive thin film for example is a metal thin film antenna. The substrate 101 for example is made of a polyethylene terephthalate (PET) material. The substrate 101 includes a metal thin film antenna pre-coated on the upper surface of the substrate 101. The metal thin film antenna includes a plurality of solder pads. The fixing thread 102 is then used to sew at the solder pads of the metal thin film antenna of the substrate 101 and through the substrate 101, and the end of the signal line 20 is welded to the solder pads of the metal thin film antenna and secured to the fixing thread 102. In such a way, a signal communication between the metal thin film antenna and the signal line 20 can be established.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. An electric connection structure, comprising:
a substrate;
a solder, welded on a surface of the substrate; and
at least one fixing thread, synchronously winding up the substrate and the solder for fixing the solder to the surface of the substrate.

2. An electric connection structure, comprising:
a substrate;
a solder, welded on a surface of the substrate; and
at least one fixing thread, synchronously sewing the substrate and the solder together for fixing the solder to the surface of the substrate.

3. An electric connection structure, comprising:
a substrate;
at least one fixing thread, being fixed to an upper surface of the substrate and extending through at least one through hole of the substrate; and
a solder, being welded on the upper surface of the substrate and covering at least a section of the fixing thread.

4. The electric connection structure as claimed in claim 3, wherein the substrate comprises a plurality of through holes positioned nearby the solder.

5. The electric connection structure as claimed in claim 4 wherein the fixing thread shuttles through the through holes.

6. The electric connection structure as claimed in claim 3 wherein the fixing thread extends through the solder.

7. The electric connection structure as claimed in claim 3 wherein the fixing thread alternatively shuttles between the upper surface and a bottom surface of the substrate.

8. The electric connection structure as claimed in claim 3 wherein the fixing thread synchronously sews the substrate together with the solder.

9. The electric connection structure as claimed in claim 3 wherein a bare end of a signal line is welded by the solder to the substrate.

10. The electric connection structure as claimed in claim 3 wherein the fixing thread is made of a conductive material.

11. The electric connection structure as claimed in claim 3 wherein a bottom surface of the substrate is sewed to an additional object by the fixing thread, and the upper surface of the substrate is provided for being welded by the solder.

12. A method for fabricating an electric connection structure, comprising:
(a) fixing at least one fixing thread on an upper surface of a substrate; and
(b) welding a solder to the upper surface of the substrate at where the fixing thread is fixed, wherein the fixing thread fixes the solder to the upper surface of the substrate.

13. The method as claimed in claim 12, further comprising: welding a bare end of a signal line to the upper surface of the substrate at where the fixing thread is fixed.

14. The method as claimed in claim 12, wherein the fixing thread alternatively shuttles between the upper surface and a bottom surface of the substrate, or winds up the upper surface and a bottom surface of the substrate.

15. The method as claimed in claim 12, wherein the fixing thread is fixed to the substrate by sewing thereon.

16. The method as claimed in claim 12, wherein a bottom surface of the substrate is sewed to an additional object by the fixing thread, and the upper surface of the substrate is provided for being welded by the solder.

17. The method as claimed in claim 12, wherein the upper surface of the substrate further comprises a metal thin film circuit layout plated thereon.

18. The method as claimed in claim 12, wherein the upper surface of the substrate further comprises a metal thin film circuit layout attached thereon.

19. The method as claimed in claim 12, wherein the upper surface further comprises a conductive thin film plated thereon.

20. The method as claimed in claim 19, wherein the conductive thin film is a metal thin film antenna.
